(19) United States
(12) Patent Application Publication
(10) Pub. No.: US 2015/0099350 A1
(43) Pub. Date: Apr. 9, 2015

(54) ENABLING HIGH ACTIVATION OF DOPANTS IN INDIUM-ALUMINUM-GALIUM-NITRIDE MATERIAL SYSTEM USING HOT IMPLANTATION AND NANOSECOND ANNEALING

(71) Applicant: Applied Materials, Inc., Santa Clara, CA (US)

(72) Inventors: Swaminathan T. SRINIVASAN, Pleasanton, CA (US); Fareen Adeni KHAJA, Gloucester, MA (US)

(21) Appl. No.: 14/503,631

(22) Filed: Oct. 1, 2014

Related U.S. Application Data
(60) Provisional application No. 61/887,587, filed on Oct. 7, 2013.

(51) Int. Cl. H01L 21/265; H01L 21/324

(52) U.S. Cl. CPC H01L 21/26546; H01L 21/3245
USPC 438/522; 438/530

(57) ABSTRACT

Embodiments of the present disclosure generally relate to doping and annealing substrates. The substrates may be doped during a hot implantation process, and subsequently annealed using a nanosecond annealing process. The combination of hot implantation and nanosecond annealing reduces lattice damage of the substrates and facilitates a higher dopant concentration near the surface of the substrate to facilitate increased electrical contact with the substrate. An optional capping layer may be placed over the substrate to reduce outgassing of dopants or to control dopant implant depth.

### CROSS-REFERENCE TO RELATED APPLICATIONS

This application claims benefit of U.S. Provisional Patent Application Ser. No. 61/887,587, filed Oct. 7, 2013, which is herein incorporated by reference.

### BACKGROUND OF THE DISCLOSURE

1. Field of the Disclosure

Embodiments of the disclosure generally relate to doping and annealing substrates, such as semiconductor substrates.

2. Description of the Related Art

Group III-V or II-V compounds are finding greater importance in the development and fabrication of a variety of semiconductor devices, such as light emitting diodes (LEDs), laser diodes (LDs), and logic circuit devices such as field effect transistors (FETs). In these devices, a plurality of semiconductor layers having different mixed crystal compositions are layered together to obtain intended optical and electrical characteristics.

However, growing a low resistivity, high quality p-type Group III-V compound on a substrate with a desired doping profile has provided unsatisfactory characteristics. Taking GaN as an example, the Group V element (i.e., nitrogen) which has a relatively high vapor pressure tends to be volatile when the GaN crystal is heated at elevated temperatures to activate implanted dopant species therein, leading to decomposition of the GaN through loss of nitrogen (i.e., nitrogen vacancies) in the GaN lattice. If surface decomposition occurs, the crystallinity of compound semiconductors tends to be degraded.

In addition, efforts to dope the GaN film p-type have been unsuccessful since GaN is naturally an n-type doped semiconductor material with high carrier concentration. The n-type characteristic is attributed in part to nitrogen vacancies in the crystal structure which are formed as a result of GaN decomposition at elevated temperatures as discussed above. Therefore, a suitable p-type dopant species is typically introduced during the GaN growth to obtain a p-type doped GaN.

Many devices require a free carrier concentration in the p-type doped GaN of at least 10¹⁸ atoms/cm³; however, p-type-doped GaN is suffering from insufficient carrier concentration since the effect of a dopant impurity is greatly reduced by a high amount of nitrogen vacancies. Also, in many situations, the effect of the dopant impurity is “neutralized” or “inactivated” by unintentional H passivation due to the formation of hydrogen complexes with dopant atoms, particularly when hydrogen containing gases, such as NH₃ gas, are used in the processing atmosphere. Therefore, only a few percent of p-type dopant atoms are activated, which contributes to non-ideal tradeoffs in structure, composition, and device performance.

Previous attempts to increase the total amount of activated p-type dopant have included implanting a higher concentration of p-type dopant into the substrate. However, such attempts result in unsatisfactory degradation of substrate crystalline structure due to excessive implanting. Therefore, there is a need for an improved method for forming high quality, highly activated doped materials on a substrate.

### SUMMARY OF THE DISCLOSURE

Embodiments of the present disclosure generally relate to doping and annealing substrates. The substrates may be doped during a hot implantation process, and subsequently annealed using a nanosecond annealing process. The combination of hot implantation and nanosecond annealing reduces lattice damage of the substrates and facilitates a higher dopant concentration near the surface of the substrate to facilitate increased electrical contact with the substrate. An optional capping layer may be placed over the substrate to reduce outgassing of dopants or to control dopant implant depth.

In one embodiment, a method of processing a substrate comprises implanting a dopant into a substrate during a hot implant process, wherein during the hot implant process the substrate is maintained at a temperature within a range of about 80 degrees Celsius to about 600 degrees Celsius, and annealing the substrate during a nanosecond annealing process to activate the dopant and to repair crystalline defects in the substrate, wherein during the nanosecond annealing process the substrate is exposed to one or more pulses of laser energy each having a duration less than about 10 microseconds.

In another embodiment, a method of processing a substrate comprises implanting a dopant into a substrate during a hot implant process, wherein during the hot implant process the substrate is maintained at a temperature less than about 500 degrees Celsius; and annealing the substrate during a nanosecond annealing process to activate the dopant and to repair crystalline defects in the substrate, wherein during the nanosecond annealing process the substrate is exposed to one or more pulses of laser energy each having a duration less than about 10 microseconds and the substrate remains solid.

In another embodiment, a method of processing a substrate, comprises implanting a dopant into a substrate during a hot implant process, wherein during the hot implant process the substrate is maintained at a temperature between about 300 degrees Celsius about 400 degrees Celsius; and annealing the substrate during a nanosecond annealing process to activate the dopant and to repair crystalline defects in the substrate, wherein during the nanosecond annealing process the substrate is exposed to one or more pulses of laser energy each having a duration between about 1 nanosecond and about 10 nanoseconds and the substrate remains solid.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1A depicts an on implanter system in which techniques for temperature-controlled ion implantation may be implemented in accordance with an embodiment of the present disclosure.

FIG. 1B illustrates the platen of FIG. 1A.

FIG. 2A illustrates a schematic isometric view of an anneal apparatus that is adapted to perform an annealing process described within an embodiment herein.

FIG. 2B illustrates a schematic side view of the anneal apparatus of FIG. 2A.

FIG. 3 illustrates a flow diagram for processing a substrate, according to one embodiment of the disclosure.

FIG. 4 illustrates a cluster tool in which embodiments described herein may be performed.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Embodiments of the present disclosure generally relate to doping and annealing substrates. The substrates may be doped during a hot implantation process, and subsequently annealed using a nanosecond annealing process. The combination of hot implantation and nanosecond annealing reduces lattice damage of the substrates and facilitates a higher dopant concentration near the surface of the substrate to facilitate increased electrical contact with the substrate. An optional capping layer may be placed over the substrate to reduce outgassing of dopants or to control dopant implant depth.

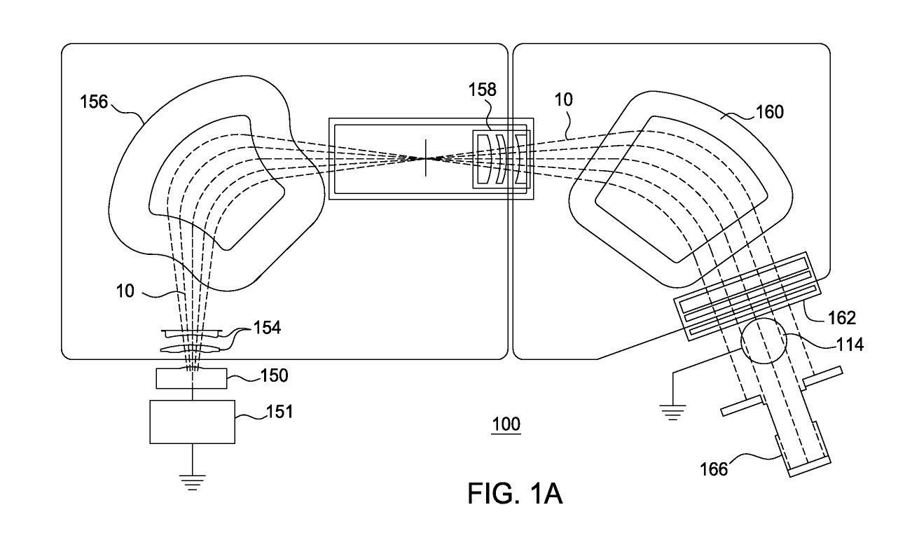

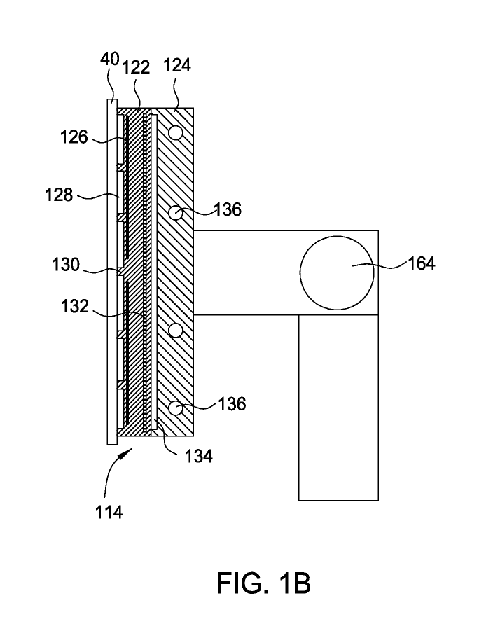

FIG. 1A depicts an on implanter system 100 in which techniques for temperature-controlled ion implantation (e.g., a hot implant) may be performed in accordance with embodiments of the present disclosure. The ion implanter system 100 may comprise an on source 150, biased to a potential by a power supply 151, and a series of beam-line components through which an ion beam 10 passes. The series of beam-line components may include, for example, extraction electrodes 154, a 90° magnet analyzer 156, a first deceleration stage 158, a 70° magnet collimator 160, and a second deceleration stage 162. Much like a series of optical lenses that manipulate a light beam, the beam-line components can filter and focus the on beam 10 before steering the on beam 10 towards a substrate, such as a semiconductor wafer. During ion implantation, the substrate is typically mounted on a platen 114 that can be moved in one or more dimensions (e.g., translate, rotate, and tilt). The ion beam 10 may be measured with one or more devices, such as a Faraday cup 166.

FIG. 1B illustrates the platen 114 of FIG. 1A. The platen 114 may be utilized for high-temperature ion implantation in accordance with one or more embodiments of the present disclosure. The entire platen 114 may be coupled to a scanner mechanism 164 that facilitates various movements of the platen 114. The platen 114 may comprise a dielectric plate 122 and an interface plate 124. The dielectric plate 122 may have electrodes 126 embedded therein to apply an electrostatic force to hold a substrate 40 onto a surface of the dielectric plate 122. The surface of the dielectric plate 122 may either be smooth or contain mesa structures 130 to reduce backside contact to the substrate 40 and to reduce backside particles. An interface 128 formed between the substrate 40 and the dielectric plate 122 may contain a backside gas to improve or adjust thermal contact therebetween. In addition, one or more heating elements 132 may be embedded in the dielectric plate 122 to heat the dielectric plate 122 and the substrate 40, and to maintain a desired elevated temperature during ion implantation. In one example, the substrate 40 may be heated using heating elements 132 which may include, for example, resistive heating elements.

The interface plate 124 may be coupled to the dielectric plate 122 via an interface 134. The interface plate 124 may be an aluminum block containing water/coolant channels 136. The interface plate 124 may also be made of other materials such as titanium, stainless steel, quartz or ceramic, which may be chosen to match the thermal expansion coefficient of different parts of the platen 114 at desired operating temperatures. The interface plate 124 may have a controlled thermal contact with the dielectric plate 122 which can be adjusted through the interface 134. For example, the interface 134 may contain a backside gas that may be evacuated when thermal isolation from the dielectric plate 122 is desired. When filled with the backside gas, the interface 134 may increase heat exchange between the interface plate 124 and the dielectric plate 122 to facilitate cooling. To expedite the cooling of the platen 114, the interface 134 may be filled with a backside gas that increases the thermal conductivity from the dielectric plate 122 to the interface plate 124. The cool down rate may be controlled by varying the backside gas pressure (in the interface 134) and/or the coolant flow rate (in the coolant channels 136).

The platen 114 facilitates a “hot implant” of the substrate 40. During the implant process, the substrate 40 is elevated to and maintained at temperature above ambient. In one example, the substrate may be maintained at a temperature of about 80 degrees Celsius to about 600 degrees Celsius. The increased temperature during implant facilitates the repair of damage caused to the crystalline structure of the substrate 40 due to the impact of energized ions with the substrate 40 during the implant process. Thus, a reduced number or size of defects exists after a hot implant process as compared to an implant process performed at room temperature.

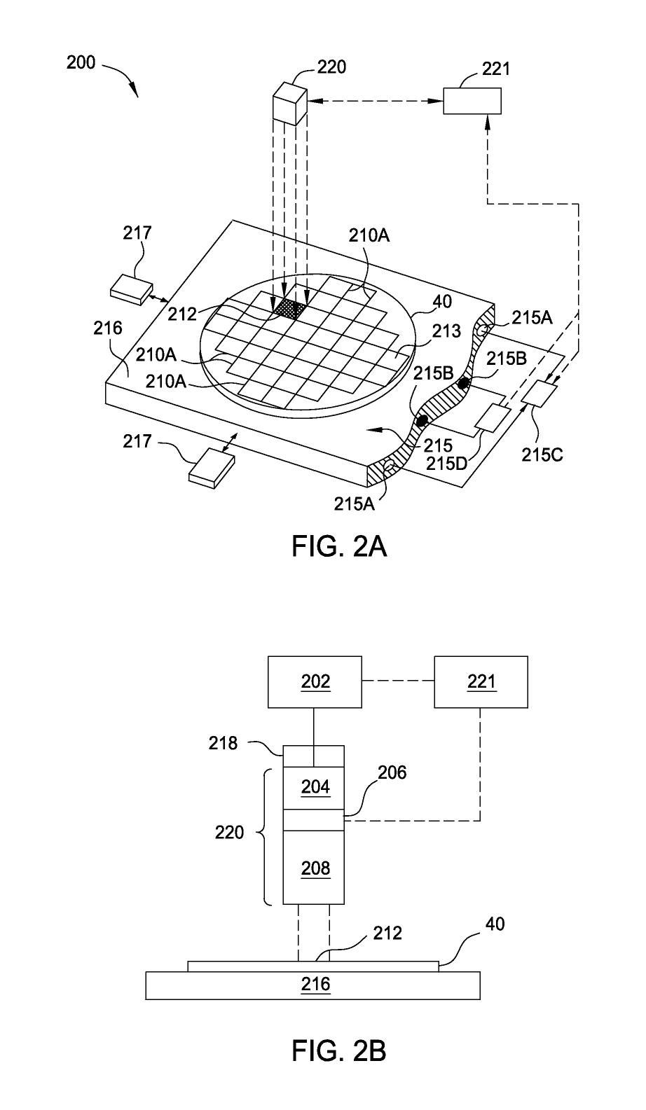

FIG. 2A illustrates a schematic isometric view of an anneal apparatus 200 that is adapted to perform an annealing process described within an embodiment herein. For example, the anneal apparatus 200 may perform a nanosecond anneal process to activate dopants within a substrate and to correct crystalline defects within the substrate. In one embodiment, an energy source 220 is adapted to project an amount of energy on a defined region, or an anneal region 212, of the substrate 40 to preferentially anneal certain desired regions within the anneal region 212. In one embodiment, as shown in FIG. 2A, only one or more defined regions of the substrate 40, such as anneal region 212, are exposed to the radiation from the energy source 220 at any given time. In one aspect of the disclosure, a single area of the substrate 40 is sequentially exposed to a desired amount of energy delivered from the energy source 220 to cause preferential annealing of desired regions of the substrate 40. Typically, one or more electrical actuators 217 (e.g., linear motor, lead screw and servo motor), which may be part of a separate precision stage (not shown), are used to control the movement and position of substrate 40.

In one aspect shown in FIG. 2A, the anneal region 212, and radiation delivered thereto, is sized to match the size of a die 213 (e.g., 40 “die” are shown in FIG. 2A), or semiconductor devices (e.g., memory chips), that are formed on the surface of the substrate 40. In one aspect, the boundary of the anneal region 212 is aligned and sized to fit within the “kerf” or “scribe” lines 210A that define the boundary of each die 213. Sequentially placing anneal regions 212 so that they only overlap in the naturally occurring unused space/boundaries between die 213, such as the scribe or kerf lines, reduces the need to overlap the energy in the areas where the devices are formed on the substrate and thus reduces the variation in the process results between the overlapping anneal regions. In one example, the area of each of the sequentially placed anneal regions 212 formed on the surface of the substrate is between about 4 mm² (e.g., 2 mm×2 mm) and about 1000 mm² (e.g., 25 mm×40 mm). It is contemplated that the size and shape of the edges of the anneal regions 212 is adjustable upon the need of processing schemes.

The energy source 220 is generally adapted to deliver electromagnetic energy to preferentially anneal certain desired regions of the substrate surface. Typical sources of electromagnetic energy include, but are not limited to, an optical radiation source (e.g., laser or flash lamps), an electron beam source, an ion beam source, and/or a microwave energy source. In one example, the multiple pulses of energy from the energy source 220 are tailored so that the amount of energy delivered across the anneal region 212 and/or the amount of energy delivered over the period of the pulse is optimized so as not to melt, or nearly melt, the anneal region or a crystalline seed region that has been previously deposited on the substrate surface. Rather, the multiple pulses of energy from the energy source 220 are tailored to deliver enough energy to promote epitaxial re-growth, for example, epitaxial regrowth of the amorphous layer progressively from the surface of the crystalline seed region. Therefore, a significant portion of the crystalline seed region underneath the annealed regions is activated and propagates throughout the amorphous layer, thereby recrystallizing the amorphous layer deposited thereabove.

In one embodiment, the wavelength of the energy source 220 is tuned so that a significant portion of the radiation is absorbed by a layer disposed on the substrate 40. For an anneal process performed on a silicon containing layer, for example, the wavelength of the radiation may be less than about 800 nm, and can be delivered at deep ultraviolet (UV), infrared (IR) or other desirable wavelengths. In one example, a substrate including GaN may be irradiated with radiation at a wavelength of about 365 nm or less. In another embodiment, an InGaN may be irradiated with radiation at a wavelength of about 460 nm or less. Due to the difference in absorption wavelength of light for different materials, it is contemplated that “selective annealing” of portions of the substrate may be performed by tuning the wavelength of the light source to preferentially heat desired regions of the substrate. It is contemplated that the use of different wavelengths of light can be used to selectively anneal different regions of the surface of the substrate, as well as different layers of a vertically-stacked device. For example, a radiation wavelength may be selected to pass through an uppermost layer of a structure, and to be absorbed (and thus anneal or activate) an underlying layer of the structure.

In one embodiment, the energy source 220 is an intense light source, such as a laser, that is adapted to deliver radiation at a wavelength between about 500 nm and about 11 micrometers. In another embodiment, the energy source 220 may be a tungsten halogen lamp or a flash lamp featuring a plurality of radiation-emitting lamps, such as xenon, argon, or krypton discharge lamps. In all cases, the energy pulse used in the anneal process generally takes place over a relatively short time, such as on the order of about 1 nanosecond to about 10 milliseconds, and may be referred to herein as a “nanosecond anneal.”

FIG. 2B is a schematic side view of the apparatus 200 of FIG. 2A. A power source 202 is coupled to the energy source 220. The energy source 220 may include an energy generator 204, which may be a light source such as those described above, and an optical assembly 208. The energy generator 204 is configured to produce energy and direct it into the optical assembly 208, which in turn shapes the energy as desired for delivery to the substrate 40. The optical assembly 208 generally includes lenses, filters, mirrors, and the like that are configured to focus, polarize, de-polarize, filter or adjust coherency of the energy produced by the energy generator 204, with the objective of delivering a uniform column of energy to the anneal region 212.

In order to deliver pulses of energy, the energy generator 204 may contain a pulsed laser, which is configurable to emit light at a single wavelength or at two wavelengths simultaneously. In one embodiment the energy generator 204 may include an Nd:YAG laser, with one or more internal frequency converters that cause a laser head to emit light at different laser frequency. Alternatively, the energy generator 204 may be configured to emit three or more wavelengths simultaneously, or further alternatively or additionally, to provide a wavelength-tunable output. In one example, the laser head used in the energy generator 104 is Q-switched to emit short, intense pulses, with pulse duration ranging, for example, from 1 nanosecond to 1 second.

In order to realize pulsed lasers, the apparatus may contain a switch 206. The switch 206 may be a fast shutter that can be opened or closed in 1 μsec or less. Alternately, the switch 206 may be an optical switch, such as an opaque crystal that becomes clear in less than 1 microsecond when light of a threshold intensity impinges on it. The optical switch generates pulses by interrupting a continuous beam of electromagnetic energy directed toward a substrate. The switch is operated by a controller 221, and may be located inside, or outside the energy generator 204, such as coupled to or fastened to an outlet area of the energy generator 204. The controller 221 may be configured to switch the power source 102 on and off as needed, or a capacitor 218 may be provided such that it is charged by the power source 202 and discharged into the energy generator 204 by virtue of circuitry energized by the controller 221. Electrical switching by capacitor is a way of self-switching, because the energy generator 204 stops generating energy when electricity provided by the capacitor 218 falls below a certain power threshold. When the capacitor 218 is recharged by the power source 202, it can then be discharged into the energy generator 204 to generate another pulse of energy. In some embodiments, the electrical switch may be configured to switch power on or off in less than 1 nanosecond, thus facilitating a nanosecond anneal process.

In one embodiment, it may be desirable to control the temperature of the substrate during thermal processing by placing a surface of the substrate 40, as illustrated in FIG. 2A, in thermal contact with a substrate supporting surface 216 of a heat exchanging device 215. The heat exchanging device 215 is generally adapted to heat and/or cool the substrate prior to or during the annealing process to improve the post-processing properties of the annealed regions of the substrate. In general, the substrate 40 is placed within an enclosed processing environment (not shown) of a processing chamber (not shown) that contains the heat exchanging device 215. The processing environment within which the substrate resides during processing may be evacuated or contain a gas suitable to the desired process. For example, embodiments of the present disclosure may be used in deposition or implant processes that require certain gases be provided to the chamber. In one aspect shown in FIG. 2A, the heat exchanging device 215 contains resistive heating elements 215A and a temperature controller 215C that are adapted to heat a substrate disposed on a substrate supporting surface 216. The temperature controller 215C may be in communication with the controller 221.

In another embodiment, it may be desirable to cool the substrate during processing to reduce any inter-diffusion due to the energy added to the substrate during the annealing process. In processes requiring incremental melting of the substrate, cooling afterward may increase regrowth velocity, which can increase the amorphization of the various regions during processing. The heat exchanging device 215 may contain one or more fluid channels 215B and a cryogenic chiller 215D that are adapted to cool a substrate disposed on a substrate supporting surface 216. In one aspect, a cryogenic chiller 215D, which is in communication with the controller 221, is adapted to deliver a cooling fluid through the one or more fluid channels 215B.

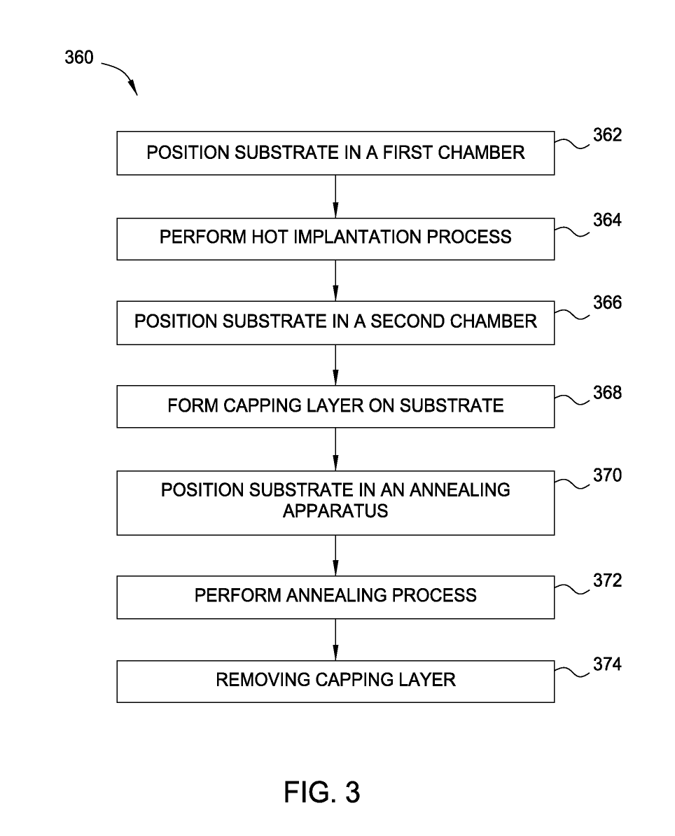

FIG. 3 illustrates a flow diagram of a method 360 for processing a substrate, according to one embodiment of the disclosure. The method 360 begins at operation 362, in which a substrate, such as a silicon, gallium arsenide (GaAs), gallium nitride (GaN), indium gallium nitride (InGaN), indium phosphide (InP), or indium aluminum gallium nitride (InAlGaN) substrate, is positioned in a first process chamber. The first process chamber may be, for example, an implantation chamber capable of implanting dopants into a substrate at an elevated temperature (e.g., a hot implant), such as the system 100 described with respect to FIG. 1. Once the substrate has been positioned in the first chamber, a hot implant process is performed in operation 364 in order to implant a dopant, such as a p-type dopant into the substrate. Examples of p-type dopants include magnesium, beryllium, calcium, strontium, barium, and zinc. The dopant may be incorporated into the substrate at a concentration of about 1×10²⁰ atoms/cm³ or greater to facilitate formation of electrical contact with the substrate by heavily doping the region directly under the contact, such as the p-GaN region, so that the near surface hole concentration is increased. In one example, a GaN layer may be doped with magnesium to a concentration greater than 1×10¹⁹ atoms/cm³ to facilitate ohmic contact therewith. In general, a III-V compound semiconductor may be doped with magnesium to a concentration greater than 1×10¹⁹ atoms/cm³ to increase p-type doping concentration in active layers and also to facilitate ohmic contact formation. It is desirable to reduce the contact resistance by doping substrate material (e.g., GaN) so that higher optical transmittance and improved optical performance can be achieved for photonics devices such as GaN based light-emitting diodes and laser diodes and improved device characteristics (low operating voltages) for electronic devices. In addition, device reliability will be improved by reducing contact resistance.

During the hot implantation process of operation 364, the substrate is maintained at a temperature within a range of about 80 degrees Celsius to about 600 degrees Celsius. For example, a silicon substrate may be maintained at a temperature less than about 500 degrees Celsius, such as about 400 degrees Celsius. In another example, a gallium arsenide substrate may be maintained at a temperature between about 80 degrees Celsius and about 600 degrees Celsius, such as about 300 degrees Celsius to about 400 degrees Celsius. By maintaining the substrate at an elevated temperature (e.g., above room temperature) during the implant, the lattice damage is reduced due to dynamic annealing, the size and amount of defects in the crystallographic structure due to implanting is reduced. The increased temperature of the substrate during processing facilitates lattice repair during processing. By performing hot implants, interstitial-vacancy (e.g., point defects) recombine quickly, resulting in fewer clusters and fewer defects. Because fewer crystal defects exist due to repair during processing, subsequent crystal repair operations can be made shorter, thereby reducing the thermal budget of the substrate as well as the amount of nitrogen or dopant outgassing that occurs due to prolonged elevated temperatures.

Further, in some embodiments, group II elements, such as beryllium, magnesium, calcium, strontium, and barium, can be co-doped with group V element such as phosphorus at room temperature or elevated temperatures to create a P+ near-surface GaN layer. The phosphorus co-implanted with magnesium helps to increase gallium vacancies, enhance activation, and reduce diffusion for p-type implants. Also, a hard mask including one or more of a photoresist, silicon dioxide, silicon nitride, spin on carbon, polyimide, advanced patterning film (APF), Topaz, or amorphous carbon can be used for patterning and selectively opening regions for doping.

Subsequent to the hot implantation process in the first chamber, the substrate is positioned in a second chamber, such as deposition chamber, in operation 366. The deposition chamber may be an atomic layer deposition (ALD) chamber, and chemical vapor depiction (CVD) chamber, a physical vapor deposition (PVD) chamber, or the like, available from Applied Materials, Inc., of Santa Clara, Calif.

In operation 368, a capping layer is formed over the substrate. The capping layer may be formed, for example, from one or more of silicon nitride, aluminum nitride, silicon, gallium nitride, or silicon dioxide, by one or more of ALD, CVD, or PVD. The capping layer may be deposited to a thickness of about 20 angstroms to about 500 angstroms, such as about 20 angstroms to about 200 angstroms. The capping layer reduces outgassing of the dopant ions from the substrate during an annealing or activation process, while also reducing the likelihood of loss of group V atoms from surface of substrate. Loss of atoms of the group V element, such as nitrogen from a gallium nitride film, can lead to decomposition of the GaN surface, thus undesirably affecting film quality. A reduction in outgassing of dopant atoms reduces the need for “over-doping” the substrate to ensure sufficient dopant remains after thermal processing. The avoidance of over-doping further reduces the occurrence of crystalline structure damage. In some examples, excessive doping of a substrate can result in unwanted substrate damage, and can also cause deactivation of the p-type dopant.

In one example, the capping layer is an AlN material which is formed by a PVD process. In such a case, the AlN material may be deposited on the substrate by reactively sputtering the Al in an argon (Ar) and nitrogen (N₂) gas mixture that is maintained at a reduced pressure, such as an environment maintained at about 0.5 mTorr to several Torr, for example, about 2 mTorr to about 300 Torr. Alternatively, the AlN material may be deposited on the substrate by RF and/or DC biasing an aluminum nitride (AlN) target in an argon (Ar) and/or nitrogen (N₂) environment to sputter the AlN material on to the surface of the substrate. It is also contemplated that the AlN material may be deposited by evaporating aluminum (Al) in a nitrogen (N₂) rich environment, or by forming the AlN layer using a CVD method.

After formation of the capping layer, the substrate is positioned in an annealing apparatus in operation 370. The annealing apparatus may be, for example, the annealing apparatus 200 described with respect to FIGS. 2A and 2B. It is contemplated, however, that other annealing apparatus capable of performing rapid high temperature anneals, such as flash annealing apparatuses utilizing lamps, may be used.

In operation 372, a nanosecond annealing process is performed on the substrate to remove the implantation-induced defects as well as to activate the dopant species. The annealing process may be any high temperature thermal annealing process that is capable of removing radiation damage and moving the dopant species onto proper substitutional lattice sites of III-V material on the substrate at an annealing temperature of about 900° C. or above, for example, about 1100 degrees Celsius to about 1500 degrees Celsius. In one example, a substrate including GaN or InGaN may be annealed at a temperature above about 1000 degrees Celsius. In some examples, the group V material may have a low dissociation temperature (around 800 degrees Celsius or above for N in GaN), thus, the required annealing temperature should desirably be reached very fast and the duration of anneal should be limited to a relatively short time, such as sub-microsecond duration, to preserve the surface morphology and the lattice quality of GaN.

During operation 372, electromagnetic radiation energy is delivered in a series of sequential pulses of energy to allow for a controlled diffusion of dopants and/or removal of implantation damage over a short distance within desired regions of a target layer or substrate. The short distance may be between about one lattice plane to tens of lattice planes. The amount of energy delivered during a single pulse is typically short enough to provide an average diffusion depth that is only a portion of a single lattice plane and thus the annealing process may require multiple pulses to achieve a desired amount of dopant diffusion or lattice damage correction. The intensity and wavelength may be tuned depending on the depth of the dopant atoms and the amount of movement desired. Wavelengths of energy used may range generally from the microwave, for example about 3 cm, through visible wavelengths, into the deep ultraviolet, for example about 150 nanometers (nm). Wavelengths ranging from about 300 nm to about 1100 nm, for example, may be used in laser applications, such as wavelengths less than about 800 nm. During the pulsed annealing process, each successive pulse constitutes a micro-anneal cycle in which energy is delivered at and propagated through the target layer (e.g., a Group III-V compound layer).

Since each pulse is sufficiently short and the additive effects of each pulse is localized and will not cause temperature to rise in the substrate, decomposition of the Group V element does not occur and the thermal budget of the substrate is not exceeded. Rather, the surface morphology is further controlled by the presence of the high concentration of Group V material region of the substrate and the capping layer (if used).

In various embodiments of the present disclosure, each pulse of the pulsed laser annealing process may deliver an energy density of about 0.2 J/cm² to about 100 J/cm² at a power level of at least 10 milliWatts (mW), such as between about 10 mW and 10 W, and the number of sequential pulses may vary between about 30 and about 100,000 pulses, each of which has a duration of about 1 nanosecond (nsec) to about 10 milliseconds (msec). The duration of each pulse may be less than 10 msec, such as between about 1 msec and about 10 msec, or between about 1 nsec and about 10 microseconds (μsec), or even less than about 100 nsec. In some examples, duration of each pulse may be between about 1 nsec and about 10 nsec, such as about 1 nsec. In another example, the duration of each pulse may be between about 2 nsec and about 200 nsec.

Prior art approaches of implanting and activating dopants have focused on only a single approach of either hot implant or laser annealing, such as nanosecond annealing, in order to reduce the thermal budget of the processed substrate. For example, some approaches have performed room temperature implants followed by an annealing process. In such an approach, the implant process often causes more damage than can be repaired in the annealing process, thus resulting in defects in final devices. Even if the thermal budget is exceeded during the annealing process in an attempt to dissolve the defects, the extent of the lattice damage may be too significant to be recovered. Additionally, dopant concentrations may be too close to the surface of the substrate to allow for melt recrystallization of the substrate. In another approach, a hot anneal has been performed without a subsequent laser or nanosecond annealing process. In such an approach, a heated support may be relied upon for elevating the temperature of a substrate to a sufficiently high temperature to activate the dopant. However, this approach also generally exceeds the desired thermal budget of the substrate, and more over, may lead to undesired outgassing of dopant atoms or Group V atoms. Additionally, this approach often does not dissolve all of the point defects in the substrate caused by the implant process.

The combination of hot implantation and nanosecond anneal provides numerous benefits over each individual process. This proposed approach enables an optimized device integration flow and provides cost of ownership benefits. The hot implantation process dissolves defects in the crystalline lattice of the substrate as the defects are created during the implant due to enhanced dynamic annealing. Increasing the implant temperature increases dynamic annealing and less point defect clusters are formed, resulting in reduced amorphization (interstitial-vacancy clusters). Thus, the likelihood of defects expanding beyond small, point defects is greatly reduced. Moreover, hot implants result in early dopant activation, e.g., during the hot implant process. Further, the remaining small, point defects can be quickly dissolved during a laser or nanosecond annealing process, simultaneously with activation of the dopants. Therefore, the thermal budget of the substrate is minimized, and crystalline structure is repaired, using a combination of a hot implant process and laser or nanosecond annealing.

Although FIG. 3 illustrates one embodiment of a method 360, other embodiments are also contemplated. In another embodiment, it is contemplated that the operations 366 and 368 of FIG. 3 may be excluded. In another embodiment, it is contemplated that operations 366 and 368 of FIG. 3 may occur before operation 362. In such an embodiment, operation 374 may occur before or after the annealing process in operation 372. When operations 366 and 368 occur prior to operation 362, the presence of the capping layer on the substrate may facilitate control of implant depth and dopant concentration near the surface of the substrate. In some examples, it may be desirable to obtain a heavy dopant concentration (such as about 1×10²⁰ atoms/cm³) close to the surface of the substrate to form an ultra-shallow junction or a highly doped p++ layer. Because dopant implant depth generally follows a Gaussian distribution, the thickness of the capping layer can be selected to position to the peak of the Gaussian distribution at a desired depth from the substrate surface, for example, from about 10 to about 200 angstroms.

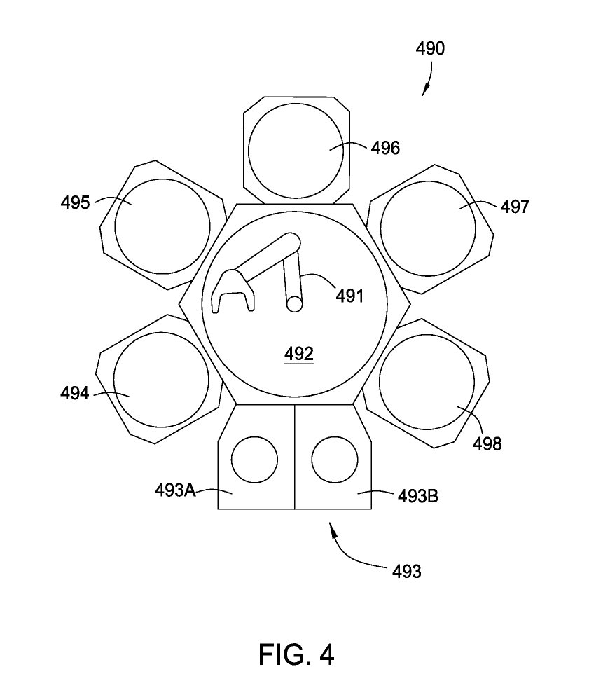

FIG. 4 illustrates a cluster tool in which embodiments described herein may be performed. The cluster tool 490 features at least one epitaxial deposition chamber, as described above. An example of the cluster tool 490 is the CENTURA® system available from Applied Materials, Inc., of Santa Clara, Calif. Cluster tools manufactured by others may be used as well. A transfer robot 491 of any convenient type is disposed in a transfer chamber 492 of the cluster tool. A load-lock 493, with two load-lock chambers 493A, 493B is coupled to the transfer chamber 492. A plurality of process chambers 494, 495, 496, 497, and 498 are also coupled to the transfer chamber 492. The plurality of process chamber 494, 495, 496, 497, and 498 may include at least one of: a preclean chamber, a material deposition chamber such as an epitaxial deposition chamber, a thermal process chamber, such as an anneal, degas, or oxidation chamber, or an implant chamber. For example, any of the process chambers 494, 495, 496, 497, and 498 may include the implant chamber discussed with respect to FIG. 1 or the annealing apparatus discussed with respect to FIGS. 2A and 2B.

Chamber 494 may be a preclean chamber configured to clean the substrate prior to deposition of a buffer layer and/or device layer. The preclean chamber may be configured to perform the Applied Materials SICONI™ Preclean process. Chamber 495 and/or 497 may be a material deposition chamber such as an epitaxial deposition chamber capable of performing an epitaxial growth process. Chamber 496 and/or 498 may be a thermal treatment chamber capable of performing a thermal treatment process, including a laser annealing process.

In this disclosure, a p-type Group III-V compound, for example GaN, is discussed. However, it is contemplated that a similar concept is applicable to n-type GaN or any other Group III-V compound semiconductors (such as, for example, GaAs, InSb, InAs, InP, GaSb, GaP, or AlSb etc.) or Group II-VI compound semiconductors (such as, for example, ZnS, ZnSe, ZnTe, CdS, CdSe, CdTe, or BeO, etc.), including binary, ternary, and quaternary alloys thereof, or growth of other semiconductors on dissimilar substrates for improvement of film properties. It is contemplated that substrates be formed from the aforementioned materials, or may include one or more layers of the aforementioned materials disposed on another material. For example, it is contemplated that a Group III-V material may be disposed on a substrate including sapphire (Al₂O₃), silicon (Si), silicon carbide (SiC), lithium aluminum oxide (LiAlO₂), lithium gallium oxide (LiGaO₂), zinc oxide (ZnO), gallium nitride (GaN), aluminum nitride (AlN), quartz, glass, gallium arsenide (GaAs), indium phosphide (InP), spinel (MgAl₂O₄), or any combination thereof, and subjected to operations disclosed herein.

Benefits of the disclosure include the ability to sufficiently dope substrate materials to desired concentrations so that higher optical transmittance, improved optical performance, and increased device reliability can be achieved. For example, barrier width manipulation by hot ion Implantation, subsequently followed by nanosecond anneal to thermally drive-in and activate dopants reduces the high contact resistance between the p-type GaN layer and a contact metal disposed thereon. Embodiments of the disclosure result in improved contact characteristics, such as reduced contact resistance, as well as GaN photonics device performance, such as higher output light extraction, better current spread (reducing the requirement for heat sink), increased reliability, and GaN electronic device characteristics. Relatively low dopant concentrations, such as below about 1×10¹⁸ atoms/cm³, undesirably result in the formation of a Schottky barriers between a metal contact disposed on a substrate, and a group III-V or II-V layer of the substrate. However, the width of the Schottky barrier is dependent upon dopant concentration, and therefore, can be sufficiently overcome when a high enough dopant concentration (e.g., above about 1×10¹⁸ atoms/cm³) is achieved. The combination of hot implanting and nanosecond annealing, described herein, allows a desirable dopant profile to be achieved while reducing crystalline defects of the substrate and improving dopant activation.

While the foregoing is directed to embodiments of the present disclosure, other and further embodiments of the disclosure may be devised without departing from the basic scope thereof, and the scope thereof is determined by the claims that follow.

What is claimed is:

1. A method of processing a substrate, comprising:
implanting a dopant into a substrate during a hot implant process, wherein during the hot implant process the substrate is maintained at a temperature within a range of about 80 degrees Celsius to about 600 degrees Celsius; and
annealing the substrate during a nanosecond annealing process to activate the dopant and to repair crystalline defects in the substrate, wherein during the nanosecond annealing process the substrate is exposed to one or more pulses of laser energy each having a duration less than about 10 microseconds and the substrate remains solid.

2. The method of claim 1, wherein the substrate comprises gallium arsenide, and wherein during the hot implantation process the substrate is maintained at a temperature less than about 500 degrees Celsius.

3. The method of claim 1, wherein the substrate comprises gallium nitride, indium phosphide, or indium gallium arsenide.

4. The method of claim 1, wherein the duration of each pulse each is between about 1 nanosecond and about 10 nanoseconds.

5. The method of claim 1, wherein the substrate is doped to a concentration of about 1×10²⁰ atoms/cm³ or greater.

6. The method of claim 1, wherein the substrate is maintained at a temperature between about 300 degrees Celsius and 400 degrees Celsius during the implanting a dopant.

7. The method of claim 1, wherein the duration of each pulse is between about 2 nanosecond and about 200 nanoseconds.

8. The method of claim 1, further comprising disposing a capping layer over the substrate.

9. The method of claim 1, wherein the substrate comprises silicon and the laser energy has a wavelength of about 800 nanometers or less.

10. The method of claim 1, wherein the substrate comprises gallium nitride and the laser energy has a wavelength of about 365 nanometers or less.

11. The method of claim 1, wherein the substrate comprises indium gallium nitride and the laser energy has a wavelength of about 460 nanometers or less.

12. The method of claim 1, wherein the substrate comprises gallium nitride and is doped with magnesium to a concentration of about 1×10¹⁹ atoms/cm³ or greater.

13. A method of processing a substrate, comprising:
implanting a dopant into a substrate during a hot implant process, wherein during the hot implant process the substrate is maintained at a temperature less than about 500 degrees Celsius; and
annealing the substrate during a nanosecond annealing process to activate the dopant and to repair crystalline defects in the substrate, wherein during the nanosecond annealing process the substrate is exposed to one or more pulses of laser energy each having a duration less than about 10 microseconds and the substrate remains solid.

14. The method of claim 13, wherein the substrate comprises silicon and the laser energy has a wavelength of about 800 nanometers or less.

15. The method of claim 13, wherein the substrate comprises gallium nitride and the laser energy has a wavelength of about 365 nanometers or less.

16. The method of claim 13, wherein the substrate comprises indium gallium nitride and the laser energy has a wavelength of about 460 nanometers or less.

17. The method of claim 13, wherein the substrate is doped to a concentration of about 1×10²⁰ atoms/cm³ or greater.

18. The method of claim 13, wherein the substrate is maintained at a temperature between about 300 degrees Celsius and 400 degrees Celsius during the implanting a dopant.

19. The method of claim 13, wherein the duration of each pulse each is between about 1 nanosecond and about 10 nanoseconds.

20. A method of processing a substrate, comprising:
implanting a dopant into a substrate during a hot implant process, wherein during the hot implant process the substrate is maintained at a temperature between about 300 degrees Celsius about 400 degrees Celsius; and
annealing the substrate during a nanosecond annealing process to activate the dopant and to repair crystalline defects in the substrate, wherein during the nanosecond annealing process the substrate is exposed to one or more pulses of laser energy each having a duration between about 1 nanosecond and about 10 nanoseconds and the substrate remains solid.
